(19) United States
(12) Patent Application Publication
(10) Pub. No.: US 2026/0344292 A1
(43) Pub. Date: Oct. 29, 2026

(54) PIEZOELECTRIC ACTUATORS

(71) Applicant: SEAGATE TECHNOLOGY LLC, Fremont, CA (US)

(72) Inventors: Xiong Liu, Singapore (SG); Lihong Zhang, Singapore (SG); Than Zaw Myint, Singapore (SG); June Christian Ang, Singapore (SG)

(21) Appl. No.: 19/186,863

(22) Filed: Apr. 23, 2025

(51) Int. Cl. H10N 30/88; G11B 5/55; H10N 30/87

(52) U.S. Cl. CPC H10N 30/883; H10N 30/872; H10N 30/877; G11B 5/5569

(57) ABSTRACT

An actuator includes a substrate with a piezoelectric material, a first layer with a material adhered to the substrate, an electrode layer with a material formed on the first layer, and a corrosion resistant layer with a material formed on the electrode layer. The material of the corrosion resistant layer is different than the material of the electrode layer.

### SUMMARY

In certain embodiments, a piezoelectric actuator of an apparatus includes a substrate with a piezoelectric material, a first layer with a material adhered to the substrate, an electrode layer with a material formed on the first layer, and a corrosion resistant layer with a material formed on the electrode layer. The material of the corrosion resistant layer is different than the material of the electrode layer.

In certain embodiments, a hard disk drive includes a piezoelectric actuator. The piezoelectric actuator has a substrate comprising a piezoelectric material, a first layer with nickel adhered to the substrate, an electrode layer with aluminum formed on the first layer, and a corrosion resistant layer with nickel and phosphorous formed on the electrode layer. In some embodiments, the corrosion resistant layer includes a first layer with the nickel and phosphorous on the electrode layer and a second layer with gold on the first layer.

While multiple embodiments are disclosed, still other embodiments of the present disclosure will become apparent to those skilled in the art from the following detailed description, which shows and describes illustrative embodiments of the present disclosure. Accordingly, the drawings and detailed description are to be regarded as illustrative in nature and not restrictive.

### BRIEF DESCRIPTION OF THE DRAWINGS

FIG. 1 shows a block diagram of a hard disk drive, in accordance with certain embodiments of the present disclosure.

FIG. 2 shows a top view of the hard disk drive of FIG. 1, in accordance with certain embodiments of the present disclosure.

FIGS. 3-5 show different views of an actuator assembly, in accordance with certain embodiments of the present disclosure.

FIG. 6 shows the piezoelectric actuator with electrodes, in accordance with certain embodiments of the present disclosure.

FIGS. 7A and 7B show bending resonance mode shapes of a piezoelectric actuator, in accordance with certain embodiments of the present disclosure.

FIG. 8 shows a piezoelectric actuator including an electrode, in accordance with certain embodiments of the present disclosure.

FIG. 9 shows a piezoelectric actuator including an electrode, in accordance with certain embodiments of the present disclosure.

FIG. 10 is a diagrammatic illustration of a piezoelectric actuator, in accordance with certain embodiments of the present disclosure.

While the disclosure is amenable to various modifications and alternative forms, specific embodiments have been shown by way of example in the drawings and are described in detail below. The intention, however, is not to limit the disclosure to the particular embodiments described but instead is intended to cover all modifications, equivalents, and alternatives falling within the scope of the appended claims.

### DETAILED DESCRIPTION

Historically, hard disk drives have used a single rotatable motor or actuator assembly to move read/write heads to a desired location to record or access data. Certain types of hard disk drives have added a second rotatable actuator assembly to increase overall data transfer rate capabilities of the hard disk drives. However, these dual-actuator designs may result in a reduction of the diameter of the magnetic recording medium (e.g., from 97 mm in a single-actuator design to 84 mm in a dual-actuator design), which may reduce the overall storage capacity of the hard disk drive.

Using linear actuator-type motors including piezoelectric materials instead of traditional rotatable actuators can help provide additional space for magnetic recording media. However, prior electrodes on the piezoelectric materials may use relatively expensive materials, such as for example the precious metals silver and gold. At least in part to reduce the costs of using such relatively expensive materials, the electrodes may be made relatively thin. For example, electrodes on the piezoelectric material may include a nichrome layer having a thickness in the range of 20 nm on the piezoelectric material for metallizing and providing adhesion to the piezoelectric material, and a gold layer (e.g., an electrode layer) having a thickness in the range of 100 nm on the nichrome layer to provide electrical conductivity and corrosion resistance. While this approach may save certain costs, such as for example material costs, electrodes of these types may have relatively high resistances, for example in the range of 2.5-7.0 ohm. In general, the higher the resistance of the electrode, the greater the power required to operate motors with such electrodes.

Certain embodiments of the present disclosure are directed to piezoelectric-based actuators or motors. Piezoelectric actuators in accordance with the embodiments described herein can be used in any of a wide range of applications. Non-limiting examples of such applications include hard disk drives with rotary and/or linear actuators. Motors of the types disclosed herein can provide certain advantages when incorporated into linear actuators, including the provision of additional space as described above. The disclosed actuators can also utilize lower-cost materials, such as, for example, non-precious metals nickel, aluminum, or copper. These linear actuators can have relatively low electrode resistances, such as for example in the range of 0.40 ohm or less, which can also reduce power requirements associated with the linear actuators. The reduced resistance provided by these electrodes benefits the systems in which they are incorporated with power and cost reductions. Heating of the piezoelectric actuators can also be reduced, thereby reducing performance degradation of the devices.

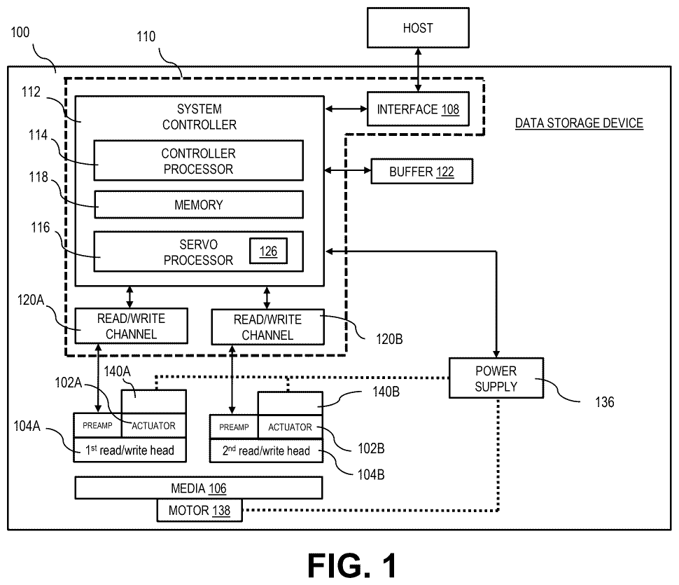

FIG. 1 shows a schematic of a data storage device 100 such as a hard disk drive that can include piezo-based linear actuators in accordance with embodiments. In the case of a hard disk drive, the data storage device 100 can include multiple actuators (i.e., a first actuator 102A and a second actuator 102B) each with one or more read/write heads 104A and 104B to provide concurrent access to magnetic recording media 106 (e.g., magnetic recording disks, which are referred to as a magnetic recording medium in singular form). In some embodiments, the multiple actuators 102A and 102B have separate pivot axes. In such embodiments, the read/write head(s) 104A coupled to the first actuator 102A can access the same magnetic recording medium 106 as the read/write head(s) 104B coupled to the second actuator 102B. Although only two actuators for the data storage device 100 are shown in FIG. 1, additional actuators can be incorporated into the data storage device 100 or the data storage device 100 may have only one actuator. The read/write heads 104A and 104B can include a magnetic sensor (e.g., the read head) and a magnetic writer (e.g., the write head).

The data storage device 100 includes an interface 108 (e.g., an input/output interface) for transferring data to and from the data storage device 100. For example, the interface 108, among other features, can be communicatively coupled between a host (e.g., a laptop or a data storage system such as a server) and the read/write heads 104A and 104B to facilitate communication, using a standardized communication protocol (e.g., SATA, SAS, SCSI), between the read/write heads 104A and 104B and the host.

The data storage device 100 can include a system on a chip (“SOC”) 110 (shown in dashed lines) that includes a system controller 112, which can include a controller processor 114 (e.g., a microprocessor), a servo processor 116 (e.g., a microprocessor), and memory 118 coupled to the controller processor 114 and the servo processor 116. The SOC 110 can include multiple distinct banks of memory. For example, one bank of memory 118 can be dedicated to the controller processor 114 and its functions while another bank of memory 118 can be dedicated to the servo processor 116 and its functions (e.g., the memory 118 and the servo processor 116 together functioning as a servo controller). The interface 108 may also be part of the SOC 110.

The SOC 110 can also include one or more read/write channels 120A and 120B, which encode data associated with write commands and with read commands. The SOC 110 may be an integrated circuit such as an application-specific integrated circuit (“ASIC”) and field-programmable gate array (“FPGA”) that includes instructions (e.g., in the form of firmware) for carrying out various functions of the data storage device 100. For example, the SOC 110 can include circuitry to control and carry out various aspects of the data storage device 100 as described in more detail below. Although the interface 108, system controller 112, etc., are shown as being part of a single SOC, the components and their functions can be distributed among several integrated circuits. The system controller 112 can be coupled to and control access to a buffer 122, which can temporarily store data associated with read commands and write commands. The buffer 122 can be a volatile memory, such as a dynamic random access memory (“DRAM”), static random access memory (“SRAM”), or other volatile memory.

During operation, the data storage device 100 receives various data transfer commands (e.g., a read command or a write command) from the host. Data associated with a write command may be received from the host by the interface 108 and initially stored to the buffer 122. The data is encoded or otherwise processed by respective read/write channels 120A or 120B and eventually stored to the magnetic recording media 106 via one of the read/write heads 104A or 104B coupled to the respective first actuator 102A or the second actuator 102B. Data associated with a read command may be retrieved from the magnetic recording media 106 and stored in the buffer 122. Such data is then transferred to the host by the interface 108.

The data storage device 100 includes a servo control system 126 that is carried out by components of the system controller 112 (e.g., the servo processor 116 and one or more banks of the memory 118).

As shown in FIG. 1, the data storage device 100 includes one or more power supplies 136, (e.g., one or more amplifiers) which are controlled by the system controller 112. The one or more power supplies 136 supply power to a motor 138 (e.g., spindle motor), which rotates the magnetic recording media 106.

The one or more power supplies 136 also supply power to actuator assemblies 140A and 140B. In certain embodiments, the power supply 136 is an integrated circuit, which includes electronics (e.g., piezoelectric motor driver electronics) designed to provide power to certain components of the actuator assemblies 140A and 140B.

The actuator assemblies 140A and 140B are used to position (e.g., linearly move) the actuators 102A and 102B to position the read/write heads 104A and 104B over a desired data track on the magnetic recording media 106 for data reading and data writing operations. For example, in response to a command to read data from or write data to a data track located a certain distance away from where a respective read/write head 104A or 104B is currently positioned, a current or voltage may be supplied by the power supply 136 and applied to piezoelectric actuators or motors of the actuator assemblies 140A and 140B to linearly move the respective actuators 102A and 102B (and therefore the respective read/write heads 104A and 104B) towards the desired data track.

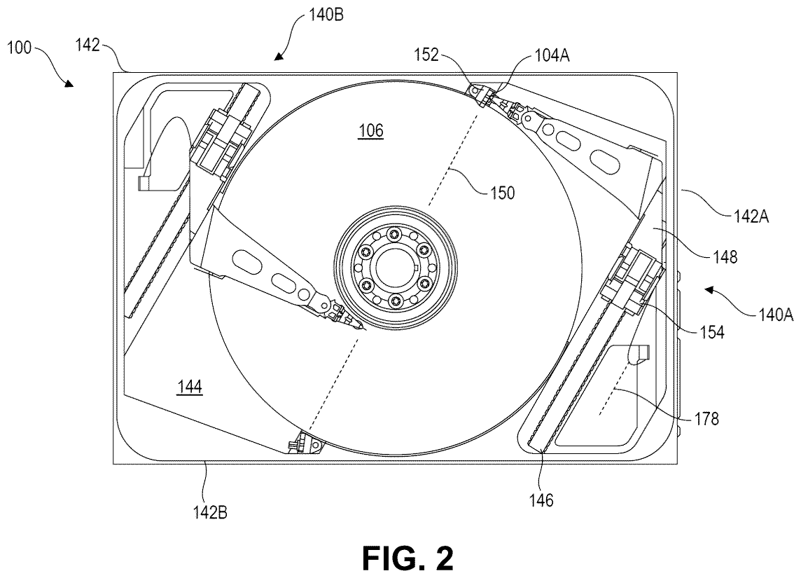

FIG. 2 shows a top view of the data storage device 100. The data storage device 100 includes sidewalls 142 around a periphery of the data storage device 100. The sidewalls 142 extend from a base 144, and the sidewalls 142 and the base 144 can be formed (e.g., cast, forged) as part of a single unit (e.g., an integrally formed unit). A top cover can be coupled (e.g., welded, fastened) to the sidewalls 142 to form a sealed enclosure (e.g., a hermetically sealed enclosure) in which various components of the data storage device are positioned.

For brevity and simplicity, the components of the actuator assemblies 140A and 140B are described below with respect to a single actuator assembly —the first actuator assembly 140A. The second actuator assembly 140B may include identical components as the first actuator assembly 140A, so the description below applies equally to both of the actuator assemblies 140A and 140B.

The actuator assembly 140A shown in FIG. 2 is configured to linearly move the read/write heads 104A (e.g., which each include respective magnetic sensors) to different positions with respect to the magnetic recording media 106. As such, the actuator assembly 140A can be considered to be a linear actuator assembly.

The actuator assembly 140A includes a stationary portion 146 and a movable portion 148. Together, the stationary portion 146 and the movable portion 148 can form a linear bearing. In certain embodiments, the stationary portion 146 is or includes a rail, and the movable portion 148 is or includes a carriage that is coupled to the stationary portion 146 such that the movable portion 148 can move with respect to the stationary portion 146.

As will be described in more detail below, the actuator assembly 140A includes a piezoelectric actuator that is configured and arranged to cause the movable portion 148 to move linearly between ends of the stationary portion 146—which ultimately causes movement of the read/write head 104A with respect to the magnetic recording medium 106. For example, the actuator assembly 140A can be arranged and configured such that movement of the movable portion 148 causes the read/write head 104A to move along a linear path 150 (represented with a dotted line). The linear path 150 can extend between an innermost data track (e.g., near an inner diameter of the magnetic recording medium 106) and an outermost data track (e.g., near an outer diameter of the magnetic recording medium 106). Further, the actuator assembly 140A can be arranged and configured such that movement of the movable portion 148 can cause the read/write head to move to a position adjacent a load/unload ramp 152. For example, a component such as a lift tab may be positioned at the distal end of the actuator assembly 140A, and the lift tab can rest on a portion of the load/unload ramp 152.

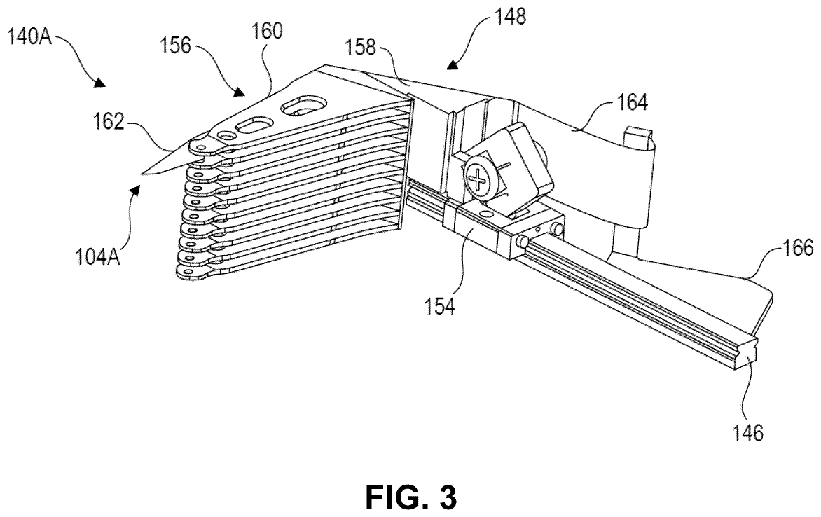

FIG. 3 shows additional details of the actuator assembly 140A. The moveable portion 148 can include a carriage portion 154, E-block portion 156, and a bridge portion 158 extending between the carriage portion 154 and the E-block portion 156. In certain embodiments, the E-block portion 156 and the bridge portion 158 form a single integral unit, but in other embodiments they are separate components that are made separately and then coupled together (e.g., fastened, welded, and the like). The E-block portion 156 and the bridge portion 158 can comprise a metal material (e.g., a metal comprising aluminum or steel (e.g., stainless steel). The E-block portion 156 can include arms 160 (e.g., one arm for each read/write head), and a suspension 162 (e.g., a component with a head-gimbal assembly (HGA)) can be coupled to each arm 160. FIG. 3 only shows one suspension and read/write head 104A, but it should be appreciated that a respective suspension and read/write head would be coupled to each arm 160. For example, because the actuator assembly 140A in FIG. 3 is shown as having ten arms 160, the hard disk drive would include nine magnetic recording media. As such, a fully assembled dual actuator design would—in total—have twenty arms, thirty-six suspensions, and thirty-six read/write heads. It should be appreciated that a different number of arms, etc., can be used with features of the actuator assembly designs described herein.

The actuator assembly 140A includes a flexible circuit 164 that facilitates data and power transfer between the read/write heads and an electrical connector assembly 166. The electrical connector assembly 166 facilitates data and power transfer to and from components inside the enclosure of the hard disk drive to and from components exterior to the hard disk drive. In certain embodiments, one or more preamps are coupled to the electrical connector assembly 166 or the flexible circuit 164.

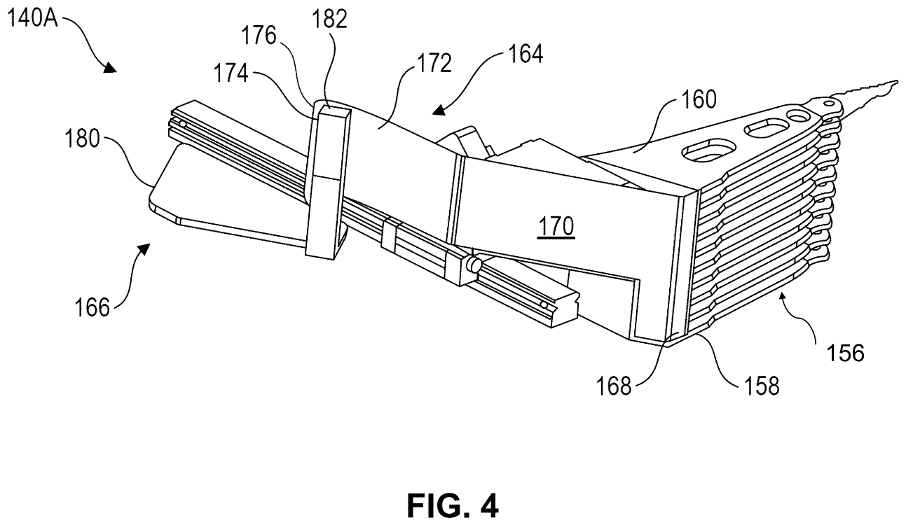

FIG. 4 shows a different view of the actuator assembly 140A. In the example of FIG. 4, the flexible circuit 164 includes multiple sections. A distal section 168 is attached to the E-block portion 156 and includes an electrical connector (e.g., a conductive portion such as a conductive bond pad) near the base of each arm 160. A wire or other type of conductive component can be mechanically and electrically coupled to each electrical connector so that data and power transfer can be facilitated between the read/write heads and the flexible circuit 164.

The flexible circuit 164 can also include a flat portion 170, a bending portion 172, and a proximal portion 174. The flat portion 170 is connected to the bridge portion 158, and the proximal portion is connected to the electrical connector assembly 166. In certain embodiments, the flexible circuit 164 includes a hinge section between the flat portion 170 and the bending portion 172. The hinge section allows the bending portion 172 to rotate relative to the flat portion 170.

The shape of the bending portion 172 will change as the movable portion 148 moves between ends of the stationary portion 146. For example, when viewed from the top (as shown in FIG. 2), the profile of the bending portion 172 will change as the movable portion 148 moves between ends of the stationary portion 146. When the movable portion 148 is closest to a first sidewall 142A (FIG. 2) and the read/write head 104A is near the outer diameter of the magnetic recording medium 106, the bending portion 172 forms a J-shape or candy-cane shape where a crest 176 (FIG. 4) or peak of the bending portion 172 is formed near the electrical connector assembly 166. When the movable portion 148 is closest to a second sidewall 142B (FIG. 2) —which is longer than the first sidewall 142A —and the read/write head 104A is near the inner diameter of the magnetic recording medium 106, the bending portion 172 forms a U-shape or V-shape where the crest 176 (FIG. 4) or peak of the bending portion 172 is formed further away from the first sidewall 142A. As the movable portion 148 moves towards the second sidewall 142B (FIG. 2), the crest 176 (FIG. 4) may follow a linear path 178 (represented by a dotted line).

Referring back to FIG. 4, the electrical connector assembly 166 includes a base portion 180 and a post 182. The base portion 180 is shaped to be coupled to the base 144 of the hard disk drive. The post 182 is mechanically coupled to the proximal portion 174 of the flexible circuit 164.

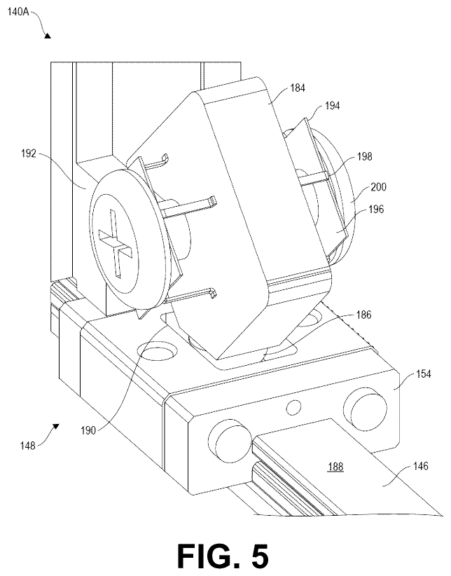

FIG. 5 shows a portion of the actuator assembly 140A, including certain features described above. The actuator assembly 140A includes a piezoelectric actuator 184. The piezoelectric actuator 184 can include a block of a piezoelectric material such as lead zirconate titanate (PZT) as well as electrodes (shown in a later Figure). When voltage is applied to the block of piezoelectric material—via the electrodes—the block will deform or vibrate in one or more (e.g., two) resonance modes. The deformation or vibration can be controlled such that the piezoelectric actuator 184 contacts the stationary portion 146 and causes the movable portion 148 to move with respect to the stationary portion 146. For example, the piezoelectric actuator 184 can include a tip portion 186 that is shaped and arranged to contact the stationary portion 146 (e.g., a top surface 188) when voltage is applied to the block of piezoelectric material. During contact, the piezoelectric actuator 184 can be further deformed to cause the relative movement of the movable portion 148 and the stationary portion 146. In certain embodiments, the block of piezoelectric material and the tip portion 186 are made from different materials. In some embodiments, the tip portion 186 comprises a ceramic material.

In the example of FIG. 5, the tip portion 186 extends at least partially through an opening 190 of the carriage portion 154. The opening 190 allows the piezoelectric actuator 184—via the tip portion 186—to contact the stationary portion 146.

The piezoelectric actuator 184 is positioned between a pair of arms 192. In certain embodiments, the piezoelectric actuator 184 does not directly contact either of the arms 192 such that there is a gap between the piezoelectric actuator 184 and the arms 192. The piezoelectric actuator 184 can be indirectly coupled to the arms 192 via preloaded spring structures 194 on opposing sides of the piezoelectric actuator 184. In the example of FIG. 5, the two preloaded spring structures 194 each include a base 196 (e.g., a flat base) and multiple legs 198 extending from the base 196. Each base 196 can have a hole through which a fastener 200 extends. The fasteners 200 are respectively coupled (e.g., via a threaded connection) to the arms 192 to hold the respective bases 196 of the preloaded spring structures 194. The preloaded spring structures 194 (via the legs 198) apply opposing forces against the piezoelectric actuator 184 such that the piezoelectric actuator 184 is held in place without contacting the arms 192. With this arrangement, the piezoelectric actuator 184 is able to deform while still being positioned between the arms 192.

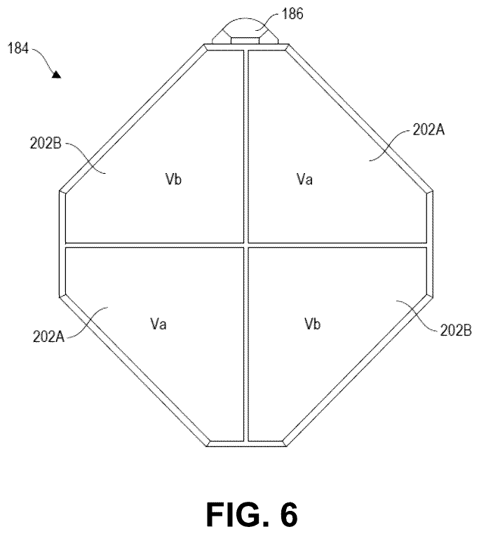

FIG. 6 shows a schematic view of the piezoelectric actuator 184 and an example arrangement of electrodes 202A-B attached to the block of piezoelectric material. Only one side of the piezoelectric actuator 184 is shown in FIG. 6, but electrodes 202A-B can be positioned on both sides of the block of piezoelectric material in a similar arrangement (e.g., a mirror image) such that the piezoelectric actuator 184 includes a total of eight electrodes (e.g., four on one side of the block of piezoelectric material and four on the opposite side of the piezoelectric material). Although the block of piezoelectric material is shown as being a diamond shaped block, other shapes can be used with the piezoelectric actuator 184. For example, the block of piezoelectric material can have a circular shape with protrusions on four sides, a flattened rhombus shape, a kite shape, or a square or rectangular shape with protrusions along its four flat sides.

Each pair of electrodes can be positioned at opposing diagonal locations along the block of piezoelectric material. For example, one electrode can be positioned between 12 o'clock and 3 o'clock along a face of the block and its pair can be positioned between 6 o'clock and 9 o'clock (and the same arrangement of electrodes can be included on the opposite side of the block of piezoelectric material). The other pair can be positioned between 3 o'clock and 6 o'clock and between 9 o'clock and 12 o'clock (and the same arrangement of electrodes can be included on the opposite side of the block of piezoelectric material).

It has been found that a diamond shaped block of piezoelectric material has two normal deformation modes when an excitation voltage is applied to the block: a bending mode and an expanding mode. With the location of the electrodes 202A-B (e.g., diagonally opposed) and certain applied excitation voltages (e.g., at a 90-degree phase difference), deformation of the block of piezoelectric material can be controlled such that the piezoelectric actuator causes the movable portion of the actuator assembly to move relative to the stationary portion. In particular, the excitation voltages can be controlled to cause the tip portion 186 to move in an elliptical motion. Such a motion can be used to cause the tip portion 186 to contact the stationary portion and move the movable portion of the actuator assembly between ends of the stationary portion. In certain embodiments, a wire is electrically coupled to each electrode to supply the voltage applied to the block of piezoelectric material.

For the electrodes shown in FIG. 6, one pair of electrodes (denoted by Va and reference number 202A) can apply an excitation voltage at a first phase to cause the piezoelectric material to deform while the other pair of electrodes (denoted by Vb and reference number 202B) can apply an excitation voltage at a second phase that has a 90-degree phase difference from the first phase. The 90-degree phase difference can be accomplished by using a sine wave for one pair of electrodes and a cosine wave for the other pair of electrodes. It has been found that applying an excitation positive voltage in a poling direction of the piezoelectric material causes the piezoelectric material to elongate along a polar axis of the material and contract in transverse direction, whereas applying an excitation positive voltage in a depoling direction of the piezoelectric material causes the piezoelectric material to contract along the polar axis and elongate in the transverse direction. In embodiments, the electrodes may share the same excitation frequency, while a phase difference exists between electrodes 202A and electrodes 202B. When two resonance frequencies are the same, a ±90° phase difference can produce the maximum motor speed.

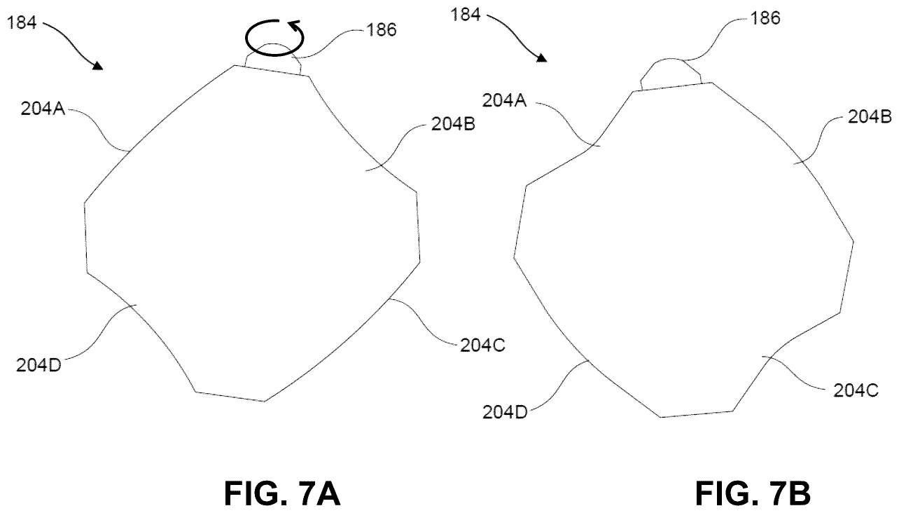

FIGS. 7A and 7B show the piezoelectric actuator 184 (e.g., the block of piezoelectric material and the tip portion 186) at different deformation or vibration resonance mode states along an elliptical-shaped stroke of the piezoelectric actuator 184. The piezoelectric actuator 184 is shown as having a diamond shape with curved or chamfered tips. Each side 204A-D of the diamond shaped piezoelectric actuator 184 is substantially flat or linear in an undeformed state (e.g., the state shown in FIGS. 5 and 6). But when excitation voltages are applied to the piezoelectric actuator 184 (e.g., via electrodes), the piezoelectric actuator 184 will deform. In certain embodiments, the piezoelectric actuator 184 has two resonance modes. Frequencies of the resonance modes may be close to one another to maximize or otherwise optimize speed of the piezoelectric actuator 184. For example, and as described herein, when both of the resonance modes are excited at a particular given frequency, the vibrations of the two resonance modes can combine to generate elliptical motion at the tip portion 186. Friction forces between the tip portion 186 and other portions of the actuator assembly 140A causes movement of the actuator assembly.

In FIG. 7A, one pair of sides 204A and 204C are deformed to form a convex shape/side profile while the other pair of sides 204B and 204D are deformed to form a concave shape/side profile. As such, the length between the concave sides 204B and 204D is less than the length between the convex sides 204A and 204C. In this deformation state, the tip portion 186 is moved towards the closest concave side 204B.

In FIG. 7B, the excitation voltages applied to the piezoelectric actuator 184 have changed such that the shapes of the pair of sides have switched from the deformation state shown in FIG. 7A. In the deformation state in FIG. 7B, the tip portion 186 is moved towards the closest concave side 204A. By cycling through these two deformation states (e.g., at ultrasonic frequencies), the piezoelectric actuator 184 can be controlled to move the movable portion of the actuator assembly back and forth along the stationary portion. This movement moves the E-block and read/write heads to different data tracks on the magnetic recording medium to record and/or access data.

The actuator assemblies 140A and 140B described herein provide benefits compared to traditional voice coil motors such as a smaller footprint, less power consumption, less heat generation, less mass, easier assembly, and less use of rare earth materials (e.g., neodymium magnets). The actuator assemblies 140A and 140B are structured and arranged to move read/write heads along a linear path as opposed to a curved path with traditional voice coil motors. The read/write heads can be arranged such that there is a fixed and/or zero skew between the reader and writer with respect to a data track on the magnetic recording medium. As such, the read/write head may be able to read data immediately after writing the data.

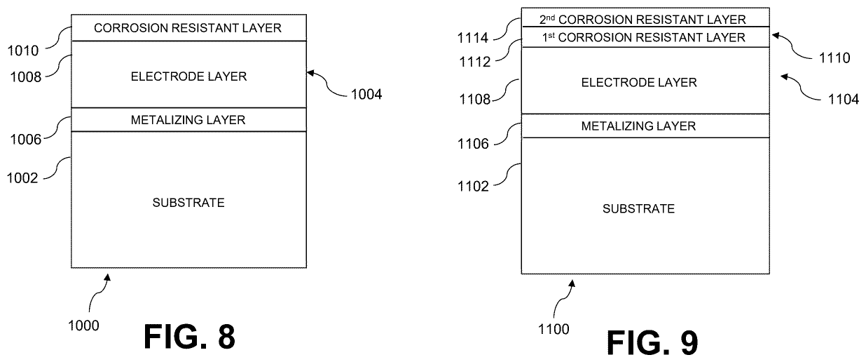

FIG. 8 is a diagrammatic illustration of a section of a piezoelectric actuator 1000 that includes a substrate 1002 and an electrode 1004 in accordance with embodiments. The illustrated section of piezoelectric actuator 1000 can, for example, be a section of any of the piezoelectric actuators described above in connection with FIGS. 1-6, 7A and 7B, such as the piezoelectric actuator 184 including the associated piezoelectric material and electrode 202A or 202B. Substrate 1002 can, for example, include piezoelectric material such as lead zirconate titanate (PZT).

The illustrated embodiments of the electrode 1004 include a first or metalizing layer 1006, a second or electrode layer 1008, and a third or corrosion resistant layer 1010. Metalizing layer 1006 can provide enhanced adhesion between the material of the substrate 1002 and materials of one or more other layers of the electrode 1004, such as for example the electrode layer 1008. In some embodiments, the metalizing layer 1006 is formed, for example by plating or other deposition processes, directly onto a surface of the substrate 1002. In some embodiments, the metalizing layer 1006 includes a non-precious metal such as nickel (Ni). For example, the metalizing layer 1006 may include an alloy comprising nickel. In some embodiments the metalizing layer 1006 consists essentially of a non-precious metal such as nickel. As used in this disclosure, a structure that “consists essentially of” a material, and similar terms, means that material with no other intentionally added elements or materials, but possibly including impurities and/or byproducts of associated manufacturing processes. Other embodiments of metalizing layer 1006 include or consist essentially of other metals, alloys or other materials.

A thickness of the metalizing layer 1006 is a thickness that is at least great enough to provide sufficient adhesion enhancing properties desired for applications of the piezoelectric actuator 1000. For example, in connection with a piezoelectric actuator 1000 configured to be incorporated into a data storage device 100 of the types described above used in normal or typical environmental conditions, a metalizing layer 1006 including or consisting essentially of nickel may have a thickness between about 10 nm and about 100 nm (e.g., 10-100 nm+/−10%). In some embodiments, for example too great of thicknesses are not necessary to provide desired functionality, and might increase mass and/or cost. In other embodiments the metalizing layer 1006 including or consisting essentially of nickel has other thicknesses. Some embodiments of metalizing layers 1006 including or consisting essentially of nickel have thicknesses less than about 100 nm but greater than 10 nm. Other embodiments of metalizing layer 1006, including for example a metalizing layer of nickel alloys or other materials, can have other thicknesses.

Electrode layer 1008 can provide relatively low resistance current distribution and transmission functionality for the electrode 1004. In some embodiments, the electrode layer 1008 is formed, for example by plating or other deposition processes, directly onto a surface of the metalizing layer 1006. Embodiments of the electrode layer 1008 include a non-precious metal such as aluminum (Al) or copper (Cu). For example, the electrode layer 1008 may be an alloy including aluminum. In some embodiments the electrode layer 1008 consists essentially of a non-precious metal such as aluminum or copper. Other embodiments of electrode layer 1008 include or consist essentially of other non-precious metals, alloys, or other materials.

A thickness of the electrode layer 1008 is a thickness that is at least great enough to provide the resistance and current distribution and transmission properties sufficient for applications of the piezoelectric actuator 1000. For example, in connection with a piezoelectric actuator 1000 configured to be incorporated into a data storage device 100 of the types described above used in normal or typical environmental conditions, an electrode layer 1008 including or consisting essentially of aluminum may have a thickness between about 400 nm and about 4000 nm. In other embodiments the electrode layer 1006 including or consisting essentially of aluminum has other thicknesses. Some embodiments of electrode layer 1008 including or consisting essentially of aluminum have thicknesses of about 2 μm. Other embodiments of electrode layer 1008, include for example an electrode layer including or consisting essentially of aluminum, aluminum alloy, copper, or other materials, can have other thicknesses.

One advantage of electrode layer 1008 of the types described herein is that the functionality of the electrode layer can be provided with relatively low-cost materials (e.g., non-precious metals such as aluminum or copper). These advantages can be achieved even though thicknesses of the electrode layer 1008 may be greater than thicknesses of other electrode layers including relatively high-cost materials such as precious metals. For example, because of the use of relatively low-cost materials, characteristics such as thickness of the electrode layer 1008 can be optimized for other properties such as resistance. These advantages from the use of these materials can be achieved using conventional and/or other efficient manufacturing processes.

Corrosion resistant layer 1010, which in the illustrated embodiment is a top and outer layer of the electrode 1004, can provide enhanced corrosion resistance to materials of one or more other layers of the electrode, such as for example the electrode layer 1008. Alternatively or additionally, the corrosion resistant layer 1010 can provide enhanced and/or good solderability to allow electrical leads to be soldered to the electrode 1004 (e.g., to the electrode layer 1008). In some embodiments, the corrosion resistant layer 1010 is formed, for example by plating or other deposition processes, directly onto a surface of the electrode layer 1008. In some embodiments, the corrosion resistant layer 1010 includes a non-precious metal such as nickel (Ni) (e.g., a material that is different than the material of the electrode layer 1008). In some embodiments, the corrosion resistant layer 1010 consists essentially of one or more non-precious metals including nickel. Embodiments of the corrosion resistant layer 1010 may include or consist essentially of an alloy including nickel. In embodiments, for example, the corrosion resistant layer 1010 includes or consists essentially of an alloy of nickel and phosphorous (P). In some embodiments, the nickel-phosphorous alloy has a relatively medium phosphorous content, such as for example phosphorous in an amount of 6%-9% by weight. Other embodiments of corrosion resistant layer 1010 include or consist essentially of other metals, alloy or materials.

A thickness of the corrosion resistant layer 1010 is a thickness that is at least great enough to provide sufficient corrosion resistant and/or soldering properties desired for applications of the piezoelectric actuator 1000. For example, in connection with a piezoelectric actuator 1000 configured to be incorporated into a data storage device 100 of the types described above used in normal or typical environmental conditions, a corrosion resistant layer 1010 including or consisting essentially of nickel and phosphorous (e.g., in an amount of 6%-9% by weight) may have a thickness between about 20 nm and about 100 nm (e.g., 20-100 nm+/−10%). In other embodiments the corrosion resistant layer 1010 including or consisting essentially of an alloy of nickel and phosphorous has other thicknesses such as for example between about 20 nm and about 100 nm. Some embodiments of corrosion resistant layers 1010 including or consisting essentially of an alloy of nickel and phosphorous have thicknesses less than about 100 nm but greater than 10 nm. Other embodiments of corrosion resistant layer 1010, including for example a corrosion resistant layer of nickel and phosphorous alloy, or other materials, can have other thicknesses.

As a non-limiting example of an electrode 1004 in accordance with embodiments, the electrode can include a metalizing layer 1006 of nickel having a thickness less than or equal to 100 nm, an electrode layer 1008 of aluminum having a thickness of approximately 2 μm, and a corrosion resistant layer 1010 of an alloy of nickel and phosphorous, such as for example with medium phosphorous content (e.g., 6%-9%) having a thickness less than or equal to approximately 2 μm. Yet other embodiments of the electrode 1004 consist essentially of a metalizing layer 1006, an electrode layer 1008 and a corrosion resistant layer 1010 of these materials. Such an electrode 1004 can, for example be suitable for applications in normal environmental conditions. Nickel adheres/bonds well to the underlying piezoelectric material substrate 1002. Bonds between aluminum and nickel or nickel-phosphorous (e.g., between electrode layer 1008 and metalizing layer 1006 and/or corrosion resistant layer 1010) are relatively strong, for example because their similar atomic radii makes their electron clouds overlap. Electrodes such as 1004 described herein can have resistances, for example, less than or equal to 0.40 ohm.

FIG. 9 is a diagrammatic illustration of a section of a piezoelectric actuator 1100 that includes a substrate 1102 and an electrode 1104 in accordance with embodiments. The illustrated section of piezoelectric actuator 1100 can, for example, be a section of any of the piezoelectric actuators described above in connection with FIGS. 1-6, 7A and 7B, such as the piezoelectric actuator 184 including the associated piezoelectric material and electrode 202A or 202B. Substrate 1102 can, for example, include piezoelectric material such as lead zirconate titanate (PZT). Electrode 1104 can be suitable for applications in highly or relatively highly corrosive environmental conditions (e.g., in applications with environmental conditions that are more corrosive than those of typical or normal environmental conditions).

The illustrated embodiments of the electrode 1104 include a first or metalizing layer 1106, a second or electrode layer 1108, and a third or corrosion resistant layer 1110. In some embodiments, the metalizing layer 1106 and electrode layer 1108 can provide functions that are substantially the same as or similar to those of the metalizing layer and electrode layer of the electrode 1004 described above, and the compositions (e.g., materials), thicknesses and manufacturing processes of the metalizing layer 1106 and electrode layer 1108 can be substantially the same as or similar to those of the metallizing layer and electrode layer, respectively, of the electrode 1004.

Corrosion resistant layer 1110 includes a first corrosion resistant layer 1112 and a second corrosion resistant layer 1114 in the illustrated embodiments. First corrosion resistant layer 1112, which in the illustrated embodiment is a bottom corrosion resistant layer (e.g., between the electrode layer 1108 and the second corrosion resistant layer 1114), can provide enhanced corrosion resistance to materials of one or more other layers of the electrode 1104, such as for example the electrode layer 1108. In some embodiments, the first corrosion resistant layer 1112 is formed, for example by plating or other deposition processes, directly onto a surface of the electrode layer 1108. In some embodiments, the first corrosion resistant layer 1112 includes a non-precious metal such as nickel (Ni). In some embodiments, the first corrosion resistant layer 1112 consists essentially of one or more non-precious metals including nickel. Embodiments of the corrosion resistant layer 1112 may include or consist essentially of an alloy including nickel. In embodiments, for example, the first corrosion resistant layer 1112 includes an alloy of nickel and phosphorous. Examples include an alloy of nickel and phosphorous. In some embodiments, the nickel-phosphorous alloy has a relatively high phosphorous content, such as for example phosphorous in an amount of 10%-14% by weight. For example, in embodiments the first corrosion resistant layer 1112 includes or consists essentially of a nickel-phosphorous alloy including about 12% phosphorous. Other embodiments of first corrosion resistant layer 1112 include or consist essentially of other metals, alloy or materials.

A thickness of the first corrosion resistant layer 1112 is a thickness that is at least great enough to provide sufficient corrosion resistant properties desired for applications of the piezoelectric actuator 1100. For example, in connection with a piezoelectric actuator 1100 configured to be incorporated into a data storage device 100 of the types described above used in relatively highly corrosive environmental conditions, a corrosion resistant layer 1112 including or consisting essentially of nickel and phosphorous (e.g., in an amount of 10%-14% by weight) may have a thickness between about 20 nm and about 100 nm. In other embodiments the first corrosion resistant layer 1112 including or consisting essentially of an alloy of nickel and phosphorous has other thicknesses such as for example between about 20 nm and about 100 nm. Some embodiments of first corrosion resistant layer 1112 including or consisting essentially of an alloy of nickel and phosphorous have thicknesses less than about 100 nm but greater than 10 nm. Other embodiments of first corrosion resistant layer 1112, including for example a corrosion resistant layer of nickel and phosphorous alloy, or other materials, can have other thicknesses.

Second corrosion resistant layer 1114, which in the illustrated embodiment is a top and outer layer of the electrode 1104, can provide enhanced corrosion resistance to materials of one or more other layers of the electrode, such as for example the first corrosion resistant layer 1112 and/or the electrode layer 1108. The second corrosion resistant layer 1114 is formed, for example by plating or other deposition processes, directly onto a surface of the first corrosion resistant layer 1112 in the illustrated embodiments.

In some embodiments, the second corrosion resistant layer 1114 includes a precious metal such as gold (Au) (e.g., a material that is different than the material of the electrode layer 1108). In some embodiments the second corrosion resistant layer 1114 consists essentially of a precious metal such as gold. Other embodiments of the second corrosion resistant layer 1114 may include an alloy including gold. Other embodiments of the second corrosion resistant layer 1114 include or consist essentially of other metals, alloys or other materials.

A thickness of the second corrosion resistant layer 1114 is a thickness that is at least great enough to provide sufficient corrosion resistance and/or solderability enhancing properties desired for applications of the piezoelectric actuator 1100. For example, in connection with a piezoelectric actuator 1100 configured to be incorporated into a data storage device 100 of the types described above used in relatively highly corrosive environmental conditions, a second corrosion resistant layer 1114 including or consisting essentially of gold may have a thickness between about 20 nm and about 100 nm. In other embodiments the second corrosion resistant layer 1114 including or consisting essentially of gold has other thicknesses such as for example between about 20 nm and about 100 nm. Some embodiments of second corrosion resistant layer 1114 including or consisting essentially of gold have thicknesses less than about 100 nm but greater than 10 nm. Other embodiments of second corrosion resistant layer 1114, including for example a second corrosion resistant layer of gold, can have other thicknesses.

As a non-limiting example of an electrode 1104 in accordance with embodiments, the electrode can include a metalizing layer 1106 of nickel having a thickness less than or equal to about 100 nm, an electrode layer 1108 of aluminum having a thickness of approximately 2 μm, a first corrosion resistant layer 1112 of an alloy of nickel and phosphorous, such as for example with high phosphorous content (e.g., 12%) having a thickness less than or equal to about 1 μm and a second corrosion resistant layer 1114 of gold having a thickness less than or equal to about 100 nm. Yet other embodiments of the electrode 1104 consist essentially of a metalizing layer 1106, an electrode layer 1108, first corrosion resistant layer 1112 and a second corrosion resistant layer 1114 of these materials. Such an electrode 1104 can, for example, be suitable for applications in highly corrosive environmental conditions. Nickel adheres/bonds well to the underlying piezoelectric material of substrate 1102. Bonds between aluminum and nickel or nickel-phosphorous are relatively strong (e.g., between electrode layer 1108, and metalizing layer 1106 and/or first corrosion resistant layer 1112), for example because their similar atomic radii makes their electron clouds overlap. Electrodes such as 1104 described herein can have resistances, for example, less than or equal to 0.40 ohm.

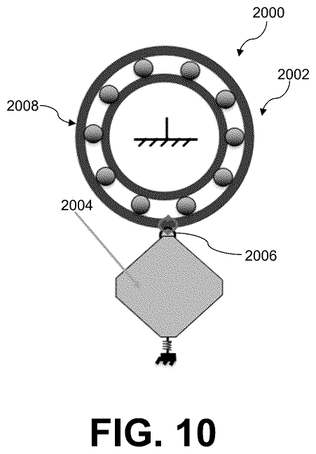

FIG. 10 is a diagrammatic illustration of a data storage device 2000 such as a hard disk drive 2000 including a piezo-based rotary actuator assembly 2002 in accordance with embodiments. As shown, the actuator assembly 2002 includes a piezoelectric actuator 2004 including a tip portion 2006 that is configured to rotationally move an assembly 2008 (e.g., an E-block) that includes read/write heads (e.g., which each include respective magnetic sensors) to different positions with respect to rotating magnetic recording media. Piezoelectric actuator 2004 can be defined by sections such as those of the piezoelectric actuators 1000 and 1100 described above in connection with FIGS. 8 and 9, and can include electrodes substantially the same as or similar to the electrodes 1004 and 1104 of the piezoelectric actuators 1000 and 1100.

This disclosure is not meant to be read in a restrictive manner. For example, the terminology used in the application should be read broadly in the context of the meaning those in the field would attribute such terminology.

Persons skilled in the art will readily appreciate that various aspects of the present disclosure can be realized by any number of methods and apparatus configured to perform the intended functions. Stated differently, other methods and apparatus can be incorporated herein to perform the intended functions. It should also be noted that the accompanying drawing figures referred to herein are not necessarily drawn to scale, but may be exaggerated to illustrate various aspects of the present disclosure, and in that regard, the drawing figures should not be construed as limiting.

Certain relative terminology is used to indicate the relative position of components and features. For example, words such as “top”, “bottom”, “upper,” “lower,” “left,” “right,” “horizontal,” “vertical,” “upward,” “downward,” “distal,” “proximal,” “leading” and “trailing” are used in a relational sense (e.g., how components or features are positioned relative to one another) and not in an absolute sense unless context dictates otherwise. Similarly, throughout this disclosure, where a process or method is shown or described, the method may be performed in any order or simultaneously, unless it is clear from the context that the method depends on certain actions being performed first.

With respect to terminology of inexactitude, the terms “about” and “approximately” may be used, in certain instances, to refer to a measurement that includes the stated measurement and that also includes any measurements that are reasonably close to the stated measurement. Measurements that are reasonably close to the stated measurement deviate from the stated measurement by a reasonably small amount as understood and readily ascertained by individuals having ordinary skill in the relevant arts. Such deviations may be attributable to measurement error, differences in measurement and/or manufacturing equipment calibration, human error in reading and/or setting measurements, minor adjustments made to optimize performance and/or structural parameters in view of differences in measurements associated with other components, particular implementation scenarios, imprecise adjustment and/or manipulation of objects by a person or machine, and/or the like, for example. In the event it is determined that individuals having ordinary skill in the relevant arts would not readily ascertain values for such reasonably small differences, the terms “about” and “approximately” can be understood to mean plus or minus 10% of the stated value.

A structure that “consists essentially of” a material, and similar terms, means that material with no other intentionally added elements or materials, but possibly including usual impurities and/or byproducts of associated manufacturing processes. The term “substantially” may be used, in certain instances, to refer to an objective, result or outcome that includes the stated objective, result or outcome, and that also includes objectives, results or outcomes that are reasonably close to the stated objective, result or outcome. Objectives, results or outcomes that are reasonably close to the stated objective, result or outcome may deviate from the stated objective, result or outcome by a reasonably small amount as understood and readily ascertained by individuals having ordinary skill in the relevant arts.

As used herein, “couple” means join, connect, attach, adhere, affix, or bond, whether directly or indirectly, and whether permanently or temporarily.

Although the embodiments herein may be described in connection with various principles and beliefs, the described embodiments should not be bound by theory. For example, embodiments are described herein in connection with hard disk drives. However, embodiments within the scope of this disclosure can be applied toward other applications.

Various modifications and additions can be made to the embodiments disclosed without departing from the scope of this disclosure. For example, while the embodiments described above refer to particular features, the scope of this disclosure also includes embodiments having different combinations of features and embodiments that do not include all of the described features. Accordingly, the scope of the present disclosure is intended to include all such alternatives, modifications, and variations as falling within the scope of the claims, together with all equivalents thereof.

We claim:

1. An apparatus comprising:
a piezoelectric actuator, including:
a substrate comprising a piezoelectric material;
a first layer comprising a material adhered to the substrate;
an electrode layer comprising a material formed on the first layer; and
a corrosion resistant layer comprising a material formed on the electrode layer, wherein the material of the corrosion resistant layer is different than the material of the electrode layer.

2. The apparatus of claim 1, wherein the first layer comprises nickel.

3. The apparatus of claim 2, wherein the first layer consists essentially of nickel.

4. The apparatus of claim 2, wherein a thickness of the first layer is less than 100 nm but greater than 10 nm.

5. The apparatus of claim 1, wherein the electrode layer comprises a non-precious metal.

6. The apparatus of claim 1, wherein the electrode layer comprises aluminum.

7. The apparatus of claim 6, wherein the electrode layer consists essentially of aluminum.

8. The apparatus of claim 1, wherein a thickness of the electrode layer is greater than 100 nm.

9. The apparatus of claim 1, wherein the piezoelectric actuator is a linear actuator.

10. The apparatus of claim 1, wherein the piezoelectric actuator is a rotatory actuator.

11. The apparatus of claim 1, wherein the corrosion resistant layer comprises nickel.

12. The apparatus of claim 11, wherein the corrosion resistant layer further comprises phosphorous.

13. The apparatus of claim 12, wherein the material of the corrosion resistant layer comprises phosphorous in an amount between 5% and 12%.

14. The apparatus of claim 12, wherein the corrosion resistant layer consists essentially of nickel and phosphorous.

15. The apparatus of claim 1, wherein the corrosion resistant layer comprises:
a first layer comprising a material on the electrode layer; and
a second layer comprising a material on the first layer, wherein the material of the second layer is different than the material of the first layer.

16. The apparatus of claim 15, wherein:
the first layer of the corrosion resistant layer comprises nickel; and
the second layer of the corrosion resistant layer comprises gold.

17. The apparatus of claim 1, wherein a resistance of the first layer, the electrode layer and the corrosion resistant layer to the substrate is less than 0.4 ohm.

18. The apparatus of claim 1, wherein the apparatus is a hard disk drive.

19. A hard disk drive comprising:
a piezoelectric actuator, including:
a substrate comprising a piezoelectric material;
a first layer comprising nickel adhered to the substrate;
an electrode layer comprising aluminum formed on the first layer; and
a corrosion resistant layer comprising nickel and phosphorous formed on the electrode layer.

20. The hard disk drive of claim 19, wherein the corrosion resistant layer comprises:
a first layer comprising the nickel and phosphorous on the electrode layer; and
a second layer comprising gold on the first layer.
